(19) United States
(12) Patent Application Publication
(10) Pub. No.: US 2008/0169730 A1
(43) Pub. Date: Jul. 17, 2008

(54) Inverted mesa quartz crystal time base reference for automatic test equipment

(76) Inventors: Romi Mayder, San Jose, CA (US); Edmundo De La Puente, Cupertino, CA (US)

Correspondence Address: VERIGY, LTD., IP LEGAL DEPARTMENT, 10100 N. TANTAU AVENUE, CUPERTINO, CA, 95014-2540, US

(21) Appl. No.: 11/652,352

(22) Filed: Jan. 11, 2007

(51) Int. Cl. H01L 41/00; H01L 41/22

(52) U.S. Cl. 310/367; 29/25.35

(57) ABSTRACT

An inverted mesa quartz crystal oscillator suitable as a time base reference for automatic test equipment is presented. The inverted mesa quartz crystal may be formed by ion beam etching a mesa in a quartz crystal substrate.

### BACKGROUND

Automatic test equipment (herein “ATE”) typically uses one or more clocks to generate accurate timing for testing and for the purpose of time measurements. Historically, a clock that introduced little or no jitter with very good overall timing accuracy is desirable. Traditionally, quartz crystals have been limited to approximately 20 MHz, beyond which frequency the crystal blank became too thin for known processing techniques.

In traditional processing of crystal substrates, the substrate is mechanically lapped to create the appropriate thickness to obtain the desired frequency. This creates a uniform thickness across the entire substrate. In the areas where the wire bond must be attached to the crystal substrate to provide the feedback path for the electrical circuit, the crystal must be mechanically robust and strong enough to withstand the wire bonding process. Hence, the crystal could not be thinned too much during the lapping process. However, a thinner crystal creates a higher frequency. Thus, the crystal would usually crack into several pieces, when an attempt was made to engineer it beyond 20 MHz.

Therefore, in order to obtain a time base reference beyond 20 MHZ, a phase lock loop has been used to increase frequency from 20 MHZ up to the desired frequency. Phase lock loops (herein “PPL”) multiply the frequency well into the hundreds of megahertz frequency range. Unfortunately, in doing so, the phase lock loops also tend to introduce short cycle and long cycle random jitter or noise into the ATE system.

Therefore, there is a need for an ATE clock that improves overall timing accuracy (herein “OTA”) of the ATE system, is capable of higher frequencies, and introduces less random jitter than traditional PPLs, in order to enable the ATE systems to test new device types and at higher date rates.

### BRIEF DESCRIPTION OF THE DRAWINGS

An understanding of the present teachings can be gained from the following detailed description, taken in conjunction with the accompanying drawings of which like reference numerals in different drawings refer to the same or similar elements:

FIG. 1 is a top view illustration of a quartz crystal oscillator according to the present teachings.

FIG. 2 is a side view illustration of a quartz crystal oscillator according to the present teachings.

FIG. 3 is a flow chart of a process according to the present teachings.

### DETAILED DESCRIPTION

In the following detailed description, for purposes of explanation and not limitation, example embodiments disclosing specific details are set forth in order to provide a thorough understanding of the present teachings. It is apparent to one having ordinary skill in the art with benefit of the present disclosure that other embodiments according to the present teachings that depart from the specific details disclosed herein remain within the scope of the appended claims. Moreover, descriptions of well-known apparatus and methods may be omitted so as to not obscure the description of the example embodiments. Such methods and apparatus are considered within the scope of the present teachings.

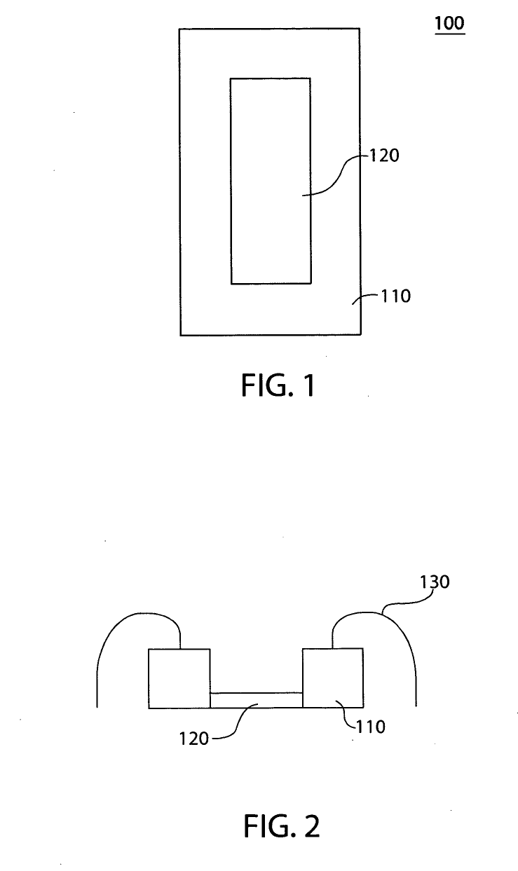

With specific reference to FIGS. 1 and 2 of the drawings, an inverted mesa quartz crystal oscillator 100 for time base reference for automatic test equipment (not shown) with an outer thick region 110, a thinner inner region 120 and wire bonds 130 is shown according to the present teachings.

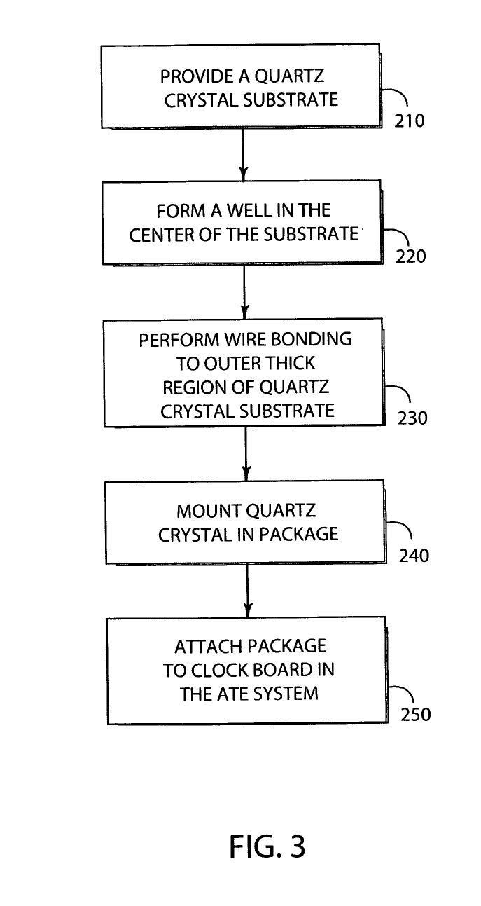

With specific reference to FIG. 3 of the drawings, there is shown a flow chart of an embodiment of a method according to the present teachings in which, a crystal blank or substrate is provided 210. The quartz crystal may be lapped to create a substantially uniform thickness across the entire blank or substrate if desired (not shown). Next, an inverted mesa or well 120 may be formed in the quartz crystal blank or substrate by etching with an ion beam in approximately the center of the substrate 220. The inverted mesa or well 120 may be thinned by the ion beam etching process to achieve up to 400 MHz operating frequency. Leads 130 may then be attached to the outer thicker regions 110 of the quartz crystal substrate 230 by wire bonding or other known means. The crystal oscillator 100 may then be mounted in a package, such as a ceramic package (not shown) 240. The package may then be soldered or otherwise attached to the clock board (not shown) inside the ATE system 250.

A quartz crystal may be made of crystalline quartz or other piezoelectric material. A quartz crystal blank or substrate may be approximately 5 mm square to 10 mm square dimensions. The thickness of the outer regions 110 may be approximately 10 mil thick. The width of the outer regions 110 may be approximately 2 mm. The inverted mesa 120 may be approximately 3 mm×3 mm and approximately 1 mil thick. It will be appreciated that the frequency of the quartz crystal may be controlled by modifying the size of the mesa or the material used. The leads 130 may be made of Gold wire bond or other similar material and attached by ball bond or wedge bond or other known means.

Empirical evidence shows that the overall timing accuracy of the ATE system was improved from +/−1000 ps to +/−650 ps by use of this inverted mesa quartz crystal oscillator as the time base reference over prior clock references. By using ion beam etching to create the inverted mesa 120, the outer perimeter 110 of the crystal blank to remain thick enough to withstand the wire bonding process without cracking or otherwise sustaining damage.

Embodiments of the teachings are described herein by way of example with reference to the accompanying drawings describing various embodiments of an apparatus and method to improve an ATE system clock. Other variations, adaptations, and embodiments of the present teachings not specifically disclosed will occur to those of ordinary skill in the art given benefit of the present teachings. For example, other embodiments with variants and combinations of components not specifically disclosed are also contemplated. For example, the inverted mesa may be etched in other than the center of the quartz crystal substrate or blank.

1. An apparatus comprising:
a quartz crystal oscillator having an thin inverted mesa at a center section of a quartz crystal substrate with a thicker outer region; and
leads attached to the thicker outer region.

2. An apparatus as recited in claim 1, wherein the thin inverted mesa is an ion beam etched thin inverted mesa.

3. An apparatus as recited in claim 1, wherein the quartz crystal oscillator is mounted in a package.

4. An apparatus as recited in claim 3, wherein the package is a ceramic package.

5. An apparatus as recited in claim 4, wherein the ceramic package with the quartz crystal oscillator is mounted to a clock board inside an ATE system.

6. A time base reference for an ATE system comprising:
a quartz crystal substrate;
an ion beam etched inverted mesa in a center portion of the quartz crystal substrate;
an outer thicker region substantially surrounding the ion beam etched inverted mesa on the quartz crystal substrate; and
wire bond leads attached to the outer thicker region on the quartz crystal substrate.

7. A time base reference for an ATE system as recited in claim 6, further comprising:
a package with the quartz crystal substrate mounted therein.

8. A method for fabricating a time base reference for an ATE system comprising:
providing a quartz crystal substrate;
etching an inverted mesa in a center portion of the quartz crystal substrate, and
attaching leads to an outer region of the quartz crystal substrate around the inverted mesa.

9. A method for fabricating a time base reference for an ATE system as recited in claim 8, wherein the etching step comprises etching an inverted mesa with an ion beam etching process.

10. A method for fabricating a time base reference for an ATE system as recited in claim 8, wherein the step of attaching leads comprises wire bonding leads to a raised outer region of the quartz crystal substrate that substantially surrounds the inverted mesa.
